(19) United States
(12) Patent Application Publication
(10) Pub. No.: US 2024/0387183 A1
(43) Pub. Date: Nov. 21, 2024

(54) CHEMICAL-MECHANICAL COMBINED MACHINING METHOD FOR SILICON CARBIDE SURFACE

(71) Applicant: HUAQIAO UNIVERSITY, Fujian (CN)

(72) Inventors: Hui HUANG, Fujian (CN); Min WU, Fujian (CN); Bonan ZHANG, Fujian (CN)

(21) Appl. No.: 18/294,174

(22) PCT Filed: Nov. 3, 2022
(86) PCT No.: PCT/CN2022/129543

§ 371 Date: Feb. 1, 2024

(30) Foreign Application Priority Data
Jan. 25, 2022 (CN) 202210086357.0

(51) Int. Cl. H01L 21/306; C09G 1/02

(52) U.S. Cl. CPC H01L 21/30625; C09G 1/02

(57) ABSTRACT

A chemical-mechanical combined machining method for a silicon carbide surface, comprising the following steps: first mounting a grinding and polishing tool (1) and silicon carbide (2) on a machine table of grinding and polishing equipment, respectively, the grinding and polishing tool (1) comprising active metal and abrasive particles which are formed in a combined mode; then pressing the silicon carbide (2) to the surface of the grinding and polishing tool (1) under the action of an external force; finally enabling the grinding and polishing tool (1) rotating at a high speed to move relative to the silicon carbide (2), thereby generating high-speed friction and inducing the active metal and the silicon carbide (2) to have a chemical reaction; and removing a reaction layer by means of mechanical action between the abrasive particles and the silicon carbide (2), thereby forming a chemical-mechanical combined cycle machining mode, and implementing surface grinding and polishing of the silicon carbide (2).

### TECHNICAL FIELD

The present invention relates to the technical field of ultra-precision machining, in particular to a chemical-mechanical composite processing method for a silicon carbide surface.

### BACKGROUND OF THE INVENTION

As a third-generation semiconductor material, silicon carbide (SiC) has excellent physical properties such as a wide band gap, high thermal conductivity, good thermal stability, and high saturation drift velocity, and is therefore widely applied in fields involving high frequency, high temperature, radiation resistance, photoelectron and the like. The industrial applications of silicon carbide require a very high surface quality of the silicon carbide, and the very high hardness and chemical inertness of silicon carbide make it difficult to process, which prevents the wide use of silicon carbide in industrial fields.

At present, the processing steps of single crystal SiC mainly involve wire saw cutting, grinding, and chemical-mechanical polishing. Chemical-mechanical polishing is the last step of silicon carbide processing. Under a proper pressure, a polishing solution is added, and a polishing pad is used to polish the surface of a silicon carbide wafer. However, the issue faced here is that the polishing solution used during the process will easily pollute the environment, and the material removal rate is low, thereby requiring a plurality of working procedures and a large amount of processing time.

Chinese patent (grant publication No. CN101966689B) discloses a surface polishing method for a carbon surface of a large-diameter 4H-SiC wafer, where an acidic polishing solution provided by the patent improves the surface polishing effect of the single crystal wafer. However, it has the problems of low polishing efficiency, excessively long polishing time, and easy contamination caused by the polishing solution.

Chinese patent (grant publication No. CN109702639B) discloses a method for grinding and polishing a SiC single crystal wafer using water-based grinding and polishing solutions to grind and polish the SiC single crystal wafer. However, it still has the problems of low material removal rate and long processing time, and the used grinding and polishing solutions are also liable to environmental pollution.

Chinese patent (grant publication No. CN108949036B) discloses a method for polishing a silicon carbide crystal, which improves the polishing rate and effect to a certain extent, but the improvement effect is limited. The problems of low polishing efficiency, long polishing time, and easy contamination caused by the polishing solution still exist.

### BRIEF SUMMARY OF THE INVENTION

### Technical Problems

The present invention aims to provide a chemical-mechanical composite processing method for a silicon carbide surface, which solves the problems such as low processing efficiency, large damage to surface and sub-surface of processed silicon carbide, and environmental pollution caused by the polishing solution in conventional silicon carbide processing technique.

### Technical Solution to the Problems

### Technical Solution

A chemical-mechanical composite processing method for a silicon carbide surface, comprising the following steps: mounting a grinding and polishing tool and a piece of silicon carbide on platforms of a grinding and polishing device respectively, where the grinding and polishing tool is actuated by the grinding and polishing device to rotate at a high speed, then pressing the silicon carbide against the grinding and polishing tool under action of an external force, so that the grinding and polishing tool rotating at a high speed rotates relatively to the silicon carbide to create high-speed frictional force against the silicon carbide, thereby achieving chemical-mechanical composite processing cycles to grind and polish the silicon carbide surface; the grinding and polishing tool comprises a composite mixture of active metals and abrasive particles; said chemical-mechanical composite processing cycles comprise the following: the active metals in the grinding and polishing tool and the silicon carbide surface are subject to chemical reaction induced by friction to generate a chemical reaction layer; then the chemical reaction layer is scraped off by mechanical action of the abrasive particles in the grinding and polishing tool to expose a fresh silicon carbide surface, thus completing a first cycle; and then, the fresh silicon carbide surface is subject to chemical reaction again with the active metals in the grinding and polishing tool to generate another new chemical reaction layer, which is then mechanically scraped off by the abrasive particles again to expose another fresh silicon carbide surface, thus completing a second cycle, and further cycles repeating same steps of the second cycle are achieved until processing of the silicon carbide is completed.

The grinding and polishing tool is prepared by hot-pressing and sintering the active metals and the abrasive particles according to a volume ratio of 7:1 to 1:1.

The active metals are metals that chemically react with a C surface of the silicon carbide or an Si surface of the silicon carbide.

The active metals chemically reacting with the C surface of the silicon carbide comprise one or more of the following: iron, cobalt, nickel, manganese, chromium, titanium, vanadium, zirconium, molybdenum, tungsten, aluminum, and niobium; the chemical reaction layer thus generated contains metal silicide and C, or contains metal carbide and Si, or contains metal carbide and metal silicide.

The active metals chemically reacting with the Si surface of the silicon carbide comprise one or more of the following: cobalt, nickel, manganese, chromium, titanium, vanadium, zirconium, molybdenum, tungsten, aluminum, and niobium; the chemical reaction layer thus generated contains metal silicide and C, or contains metal carbide and Si, or contains metal carbide and metal silicide.

The active metals comprise one or a mixture of metal elements and one or a mixture of metal alloys formed from said metal elements.

The abrasive particles comprise one or a combination of aluminum oxide, cubic boron nitride, diamond, silicon nitride, and silicon carbide.

The high-speed frictional force is achieved through dry friction or wet friction; a gas environment when the high-speed frictional force is enacted against the silicon carbide is at least one of the following: atmospheric environment, oxygen-enriched environment, and inert gas environment; an atmospheric temperature when the high-speed frictional force is enacted against the silicon carbide is room temperature or high temperature; a rotating speed of the grinding and polishing tool when the high-speed frictional force is enacted against the silicon carbide is 1-50 m/s, and a pressure of the silicon carbide pressing against the grinding and polishing tool when the high-speed frictional force is enacted against the silicon carbide is 0.1-1 Mpa.

The grinding and polishing device comprises a high-speed rotation platform and a linearly movable platform installed above the high-speed rotation platform, a main shaft of the high-speed rotation platform is driven to rotate by a rotation mechanism, the linearly movable platform is driven to perform vertical up-down movement by a transmission mechanism; the grinding and polishing tool is installed on the main shaft of the high-speed rotation platform, and the silicon carbide is installed on a clamp of the linearly movable platform.

The chemical-mechanical composite processing method for the silicon carbide surface according to the present invention adopts a method that involves grinding and polishing silicon carbide by combining friction-induced chemical reaction of metals with mechanical scraping. The method utilizes active metals to chemically react with silicon carbide under high-speed frictional force enacted to the silicon carbide by the grinding and polishing tool to generate a chemical reaction layer (metal silicide, metal carbide, Si, and C, etc.) with a softer texture, and then the generated chemical reaction layer is mechanically scraped by abrasive particles, thereby achieving high-quality and efficient removal of silicon carbide.

### Advantageous Effects of the Invention

### Advantageous Effects

The chemical-mechanical composite processing method for the silicon carbide surface has the following beneficial effects: 1. By combining chemical reaction with mechanical removal, a nearly damage-free silicon carbide surface can be obtained, with significantly less damage compared to traditional grinding and polishing method. 2. The material removal efficiency of silicon carbide according to the present invention is far higher than that of traditional chemical-mechanical polishing. 3. The present invention effectively avoids the problem of waste liquid pollution in traditional grinding and polishing processes.

### BRIEF DESCRIPTION OF THE DRAWINGS

### Description of the Drawings

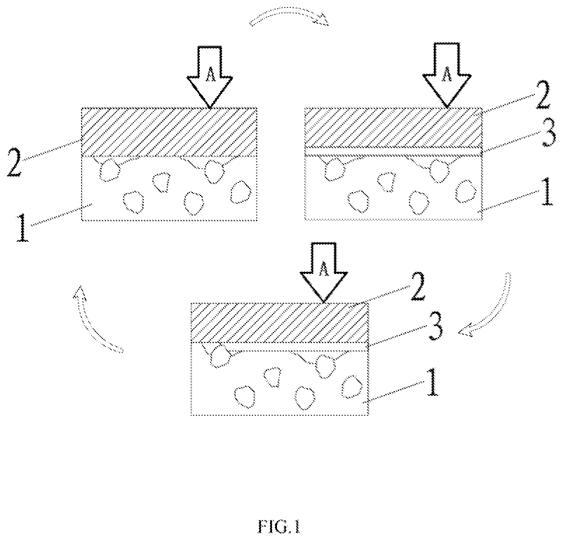

FIG. 1 is a structural schematic diagram of a grinding and polishing device according to the present invention, in which arrow “a” indicates a downward pressure and arrow “b” indicates a relative movement direction; and

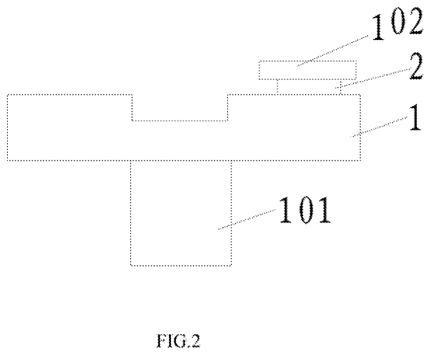

FIG. 2 is a schematic diagram of a chemical-mechanical composite processing method for a silicon carbide surface according to the present invention.

Reference signs in the figures: grinding and polishing tool 1; silicon carbide 2; chemical reaction layer 3; main shaft 101; and clamp 102.

### DETAILED DESCRIPTION OF THE INVENTION

### Embodiments of the Invention

To further explain the technical solutions of the present invention, a detailed description of the present invention is provided below through specific embodiments.

A chemical-mechanical composite processing method for a silicon carbide surface, comprising the following steps: As shown in FIG. 1, mounting a grinding and polishing tool 1 and a piece of silicon carbide 2 on platforms of a grinding and polishing device respectively, where the grinding and polishing tool 1 is actuated by the grinding and polishing device to rotate at a high speed, then pressing the silicon carbide 2 against the grinding and polishing tool 1 under action of an external force, so that the grinding and polishing tool 1 rotating at a high speed rotates relatively to the silicon carbide 2 to create high-speed frictional force against the silicon carbide 2, thereby achieving chemical-mechanical composite processing cycles to grind and polish the silicon carbide surface. The grinding and polishing tool 1 comprises a composite mixture of active metals and abrasive particles. Said chemical-mechanical composite processing cycles comprise the following: the active metals in the grinding and polishing tool 1 and the silicon carbide surface are subject to chemical reaction induced by friction to generate a chemical reaction layer 3; then the chemical reaction layer 3 is scraped off by mechanical action of the abrasive particles in the grinding and polishing tool 1 to expose a fresh silicon carbide surface, thus completing a first cycle; and then, the fresh silicon carbide surface is subject to chemical reaction again with the active metals in the grinding and polishing tool 1 to generate another new chemical reaction layer 3, which is then mechanically scraped off by the abrasive particles again to expose another fresh silicon carbide surface, thus completing a second cycle, and further cycles repeating same steps of the second cycle are achieved until processing of the silicon carbide 2 is completed.

The grinding and polishing tool 1 is prepared by hot-pressing and sintering the active metals and the abrasive particles according to a volume ratio of 7:1 to 1:1.

The active metals are metals that chemically react with a C surface of the silicon carbide 2 or an Si surface of the silicon carbide 2.

The active metals chemically reacting with the C surface of the silicon carbide 2 comprises one or more of the following: iron, cobalt, nickel, manganese, chromium, titanium, vanadium, zirconium, molybdenum, tungsten, aluminum, and niobium. If a gas atmosphere when the high-speed frictional force is enacted against the silicon carbide 2 is an inert gas atmosphere, the chemical reaction layer thus generated contains metal silicide and C, or contains metal carbide and Si, or contains metal carbide and metal silicide. If the gas atmosphere when the high-speed frictional force is enacted against the silicon carbide 2 contains oxygen, the chemical reaction layer thus generated further contains silicon dioxide.

The active metals chemically reacting with the Si surface of the silicon carbide 2 comprises one or more of the following: cobalt, nickel, manganese, chromium, titanium, vanadium, zirconium, molybdenum, tungsten, aluminum, and niobium. If a gas atmosphere when the high-speed frictional force is enacted against the silicon carbide 2 is an inert gas atmosphere, the chemical reaction layer thus generated contains metal silicide and C, or contains metal carbide and Si, or contains metal carbide and metal silicide. If the gas atmosphere when the high-speed frictional force is enacted against the silicon carbide 2 contains oxygen, the chemical reaction layer thus generated further contains silicon dioxide.

The active metals comprise one or a mixture of metal elements and one or a mixture of metal alloys formed from said metal elements.

The abrasive particles comprise one or a combination of aluminum oxide, cubic boron nitride, diamond, silicon nitride, and silicon carbide.

The high-speed frictional force is achieved through dry friction or wet friction; the gas environment when the high-speed frictional force is enacted against the silicon carbide 2 is at least one of the following: atmospheric environment, oxygen-enriched environment, and inert gas environment; an atmospheric temperature when the high-speed frictional force is enacted against the silicon carbide 2 is room temperature or high temperature; a rotating speed of the grinding and polishing tool 1 when the high-speed frictional force is enacted against the silicon carbide 2 is 1-50 m/s, and a pressure of the silicon carbide 2 pressing against the grinding and polishing tool 1 when the high-speed frictional force is enacted against the silicon carbide 2 is 0.1-1 Mpa.

As shown in FIG. 2, the grinding and polishing device comprises a high-speed rotation platform and a linearly movable platform installed above the high-speed rotation platform, a main shaft 101 of the high-speed rotation platform is driven to rotate by a rotation mechanism, the linearly movable platform is driven to perform vertical up-down movement by a transmission mechanism; the grinding and polishing tool 1 is installed on the main shaft 101 of the high-speed rotation platform, and the silicon carbide 2 is installed on a clamp 102 of the linearly movable platform. The grinding and polishing device is a well-known device in the art.

According to embodiment 1, a chemical-mechanical composite processing method for a silicon carbide surface comprises the following steps: Step 1 (preparing a grinding and polishing tool): mixing iron powder and brown fused alumina (mainly composed of aluminum oxide) evenly according to a volume ratio of 3:2 to obtain a mixture, sieving the mixture through a 100-mesh sieve to obtain sieved mixture, and then hot-pressing and sintering the sieved mixture, wherein said hot-pressing and sintering comprise the following steps: heating the sieved mixture to 300° C. at a heating rate of 3° C./min in a vacuum hot-pressing sintering machine, then further heating up to 900° C. at a heating rate of 5° C./min, preserving the heat for 30 min, and finally cooling the sieved mixture down to room temperature in the vacuum hot-pressing sintering machine; and then perform sintering to form the grinding and polishing tool; Step 2 (mounting the grinding and polishing tool): mounting the grinding and polishing tool on the main shaft of the high-speed rotation platform of the grinding and polishing device, and mounting the silicon carbide to be ground and polished on the clamp of the linearly movable platform of the grinding and polishing device; Step 3 (grinding and polishing): under the driving action of the linearly movable platform, press the silicon carbide 2 against a surface of the grinding and polishing tool 1, so that the grinding and polishing tool 1 rotating at a high speed rotates relatively to the silicon carbide 2 to create high-speed frictional force against the silicon carbide 2, thereby achieving chemical-mechanical composite processing cycles to grind and polish the silicon carbide surface.

In this embodiment, the high-speed friction is dry friction performed at room temperature in an atmospheric environment, and the rotating speed of the grinding and polishing tool when the high-speed frictional force is enacted against the silicon carbide is 10 m/s, and a pressure of the silicon carbide 2 pressing against the grinding and polishing tool 1 when the high-speed frictional force is enacted against the silicon carbide 2 is 0.2 Mpa, and a duration of processing is 10 min.

In this embodiment, the chemical-mechanical composite processing cycles comprise the following: The iron powder in the grinding and polishing tool and the C surface of the silicon carbide are subject to a chemical reaction induced by friction to generate a chemical reaction layer containing FeSi, C, and SiO2; then the chemical reaction layer is scraped off by mechanical action of the brown fused alumina serving as abrasive particles to expose a fresh silicon carbide surface, thus completing a first cycle; and then, the fresh silicon carbide surface is subject to chemical reaction again with the iron powder in the grinding and polishing tool to generate another new chemical reaction layer, which is then mechanically scraped off by the abrasive particles again to expose another fresh silicon carbide surface, thus completing a second cycle, and further cycles repeating same steps of the second cycle are achieved until processing of the silicon carbide is completed.

According to embodiment 2, a chemical-mechanical composite processing method for a silicon carbide surface comprises the following steps: Step 1 (preparing a grinding and polishing tool): mixing nickel powder and white fused alumina (mainly composed of aluminum oxide) evenly according to a volume ratio of 3:1 to obtain a mixture, sieving the mixture through a 100-mesh sieve to obtain sieved mixture, and then hot-pressing and sintering the sieved mixture, wherein said hot-pressing and sintering comprise the following steps: heating the sieved mixture to 300° C. at a heating rate of 3° C./min in a vacuum hot-pressing sintering machine, then further heating up to 900° C. at a heating rate of 5° C./min, preserving the heat for 30 min, and finally cooling the sieved mixture down to room temperature in the vacuum hot-pressing sintering machine; and then perform sintering to form the grinding and polishing tool; Step 2 (mounting the grinding and polishing tool): mounting the grinding and polishing tool on the main shaft of the high-speed rotation platform of the grinding and polishing device, and mounting the silicon carbide to be ground and polished on the clamp of the linearly movable platform of the grinding and polishing device; Step 3 (grinding and polishing): under the driving action of the linearly movable platform, press the silicon carbide 2 against a surface of the grinding and polishing tool 1, so that the grinding and polishing tool 1 rotating at a high speed rotates relatively to the silicon carbide 2 to create high-speed frictional force against the silicon carbide 2, thereby achieving chemical-mechanical composite processing cycles to grind and polish the silicon carbide surface.

In this embodiment, the high-speed friction is dry friction performed at room temperature in an atmospheric environment, and the rotating speed of the grinding and polishing tool when the high-speed frictional force is enacted against the silicon carbide is 2 m/s, and a pressure of the silicon carbide 2 pressing against the grinding and polishing tool 1 when the high-speed frictional force is enacted against the silicon carbide 2 is 0.4 Mpa, and a duration of processing is 25 min.

In this embodiment, the chemical-mechanical composite processing cycles comprise the following: The nickel powder in the grinding and polishing tool and the C surface and Si surface of the silicon carbide are subject to a chemical reaction induced by friction to generate a chemical reaction layer containing Ni2Si, C, and SiO2; then the chemical reaction layer is scraped off by mechanical action of the white fused alumina serving as abrasive particles to expose a fresh silicon carbide surface, thus completing a first cycle; and then, the fresh silicon carbide surface is subject to chemical reaction again with the nickel powder in the grinding and polishing tool to generate another new chemical reaction layer, which is then mechanically scraped off by the abrasive particles again to expose another fresh silicon carbide surface, thus completing a second cycle, and further cycles repeating same steps of the second cycle are achieved until processing of the silicon carbide is completed.

The chemical-mechanical composite processing method for the silicon carbide surface has the following beneficial effects: 1. By combining chemical reaction with mechanical removal, a nearly damage-free silicon carbide surface can be obtained, with significantly less damage compared to traditional grinding and polishing method. 2. The material removal efficiency of silicon carbide according to the present invention is far higher than that of traditional chemical-mechanical polishing. 3. The present invention effectively avoids the problem of waste liquid pollution in traditional grinding and polishing processes.

The above embodiments and illustrations are not intended to limit the form and style of the product of the present invention. Any appropriate variations or modifications made by those of ordinary skills in the art shall be considered as falling within the scope of the patent of the present invention.

1. A chemical-mechanical composite processing method for a silicon carbide surface, comprising the following steps:
mounting a grinding and polishing tool onto a main shaft, and installing a piece of silicon carbide onto a clamp, where the grinding and polishing tool is actuated by the main shaft to rotate,
then pressing the silicon carbide against the grinding and polishing tool under action of an external force, so that the grinding and polishing tool rotates relatively to the silicon carbide to create frictional force against the silicon carbide, thereby achieving chemical-mechanical composite processing cycles to grind and polish the silicon carbide surface;
the grinding and polishing tool comprises a composite mixture of active metals and abrasive particles;
said chemical-mechanical composite processing cycles comprise the following: the active metals in the grinding and polishing tool and the silicon carbide surface are subject to chemical reaction induced by friction to generate a chemical reaction layer; then the chemical reaction layer is scraped off by mechanical action of the abrasive particles in the grinding and polishing tool to expose a fresh silicon carbide surface, thus completing a first cycle; and then, the fresh silicon carbide surface is subject to chemical reaction again with the active metals in the grinding and polishing tool to generate another new chemical reaction layer, which is then mechanically scraped off by the abrasive particles again to expose another fresh silicon carbide surface, thus completing a second cycle, and further cycles repeating same steps of the second cycle are achieved until processing of the silicon carbide is completed;
the grinding and polishing tool is prepared by hot-pressing and sintering the active metals and the abrasive particles according to a volume ratio of 7:1 to 1:1;
the active metals are metals that chemically react with a C surface of the silicon carbide or an Si surface of the silicon carbide.

2. The chemical-mechanical composite processing method of claim 1, wherein the active metals chemically reacting with the C surface of the silicon carbide comprise one or more of the following: iron, cobalt, nickel, manganese, chromium, titanium, vanadium, zirconium, molybdenum, tungsten, aluminum, and niobium.

3. The chemical-mechanical composite processing method of claim 1, wherein the active metals chemically reacting with the Si surface of the silicon carbide comprise one or more of the following: cobalt, nickel, manganese, chromium, titanium, vanadium, zirconium, molybdenum, tungsten, aluminum, and niobium.

4. The chemical-mechanical composite processing method of claim 1, wherein the active metals comprise one or a mixture of metal elements and one or a mixture of metal alloys formed from said metal elements.

5. The chemical-mechanical composite processing method of claim 1, wherein the abrasive particles comprise one or a combination of aluminum oxide, cubic boron nitride, diamond, silicon nitride, and silicon carbide.

6. The chemical-mechanical composite processing method of claim 1, wherein the frictional force is achieved through dry friction or wet friction; a gas environment when the frictional force is enacted against the silicon carbide is at least one of the following: atmospheric environment, oxygen-enriched environment, and inert gas environment; an atmospheric temperature when the frictional force is enacted against the silicon carbide is room temperature; a rotating speed of the grinding and polishing tool when the frictional force is enacted against the silicon carbide is 1-50 m/s, and a pressure of the silicon carbide pressing against the grinding and polishing tool when the frictional force is enacted against the silicon carbide is 0.1-1 Mpa.

7. (canceled)
